(19) United States
(12) Patent Application Publication
(10) Pub. No.: US 2020/0271397 A1
(43) Pub. Date: Aug. 27, 2020

(54) RADIATOR FIXING STRUCTURE

(71) Applicant: TAI-SHENG HAN, New Taipei (TW)

(72) Inventor: TAI-SHENG HAN, New Taipei (TW)

(21) Appl. No.: 16/285,217

(22) Filed: Feb. 26, 2019

(51) Int. Cl. F28F 9/007; G06F 1/20; H05K 7/20

(52) U.S. Cl. CPC F28F 9/007; F28F 2275/14; H05K 7/20263; G06F 1/20

(57) ABSTRACT

The present invention provides a radiator fixing structure comprising a radiator and a base, the radiator has a plurality of convex portions and a plurality of guide portions, as well as a plurality of slide portions and a plurality of stop portions. The base is disposed on a bottom of the radiator, a center of the base has at least one positioning portion, and the positioning portion is disposed on one of the slide portions and abuts against one of the stop portions. The base is displaceable along the slide portion and one of the guide portions through the positioning portion, and is disassembled from the bottom of the radiator, thereby achieving the effect of being conveniently fixed and disassembled.

### BACKGROUND OF THE INVENTION

### Field of Invention

The present invention relates to a radiator, and more particularly to a radiator fixing structure that can be conveniently fixed and disassembled.

### Related Art

When using heating elements of internal devices of personal computers and notebook computers, such as motherboard, central processing unit, or integrated circuit components, they generate high heat during operation. The faster the processing speed, the higher the relative thermal energy produced Therefore, the execution speed is reduced or even the service life of the components will be affected. At this time, dissipating the thermal energy timely is a necessary solution, and radiator or radiator fin is usually disposed on the electronic component to increase the heat dissipation area and thereby enhancing the heat dissipation performance. However, due to the limited heat dissipation effect of the radiator and the radiator fin, the current conventional technology uses a water-cooled radiator as a solution to enhance the heat dissipation performance. In order to make the water-cooled radiator to be stably disposed, it is usually used with a support frame to fix the positions of the water-cooled radiator and the heating element, so that the water-cooled radiator does not slide easily and can maintain a better heat dissipation effect. While screws are used for fixing and locking the support frame and the water-cooled radiator, but it is quite inconvenient to assemble and lock the support frame and the water-cooled radiator together, positions between the support frame and the water-cooled radiator need to be accurately aligned in order to lock properly, and also fastening the screws is time and labor consuming, and therefore causes inconvenience in fixing and disassembling.

Therefore, how to improve the above-mentioned drawbacks is the technical difficulty that the inventor of the present invention wants to solve.

### SUMMARY OF THE INVENTION

Therefore, in order to effectively solve the above problems, a main object of the present invention is to provide a radiator fixing structure that can be conveniently fixed and disassembled.

In order to achieve the above object, the present invention provides a radiator fixing structure comprising a radiator and a base, wherein at positions of a bottom the radiator are formed with a plurality of convex portions, and at positions of the bottom the radiator are formed with a plurality of guide portions and a plurality of slide portions and a plurality of stop portions. Each of the guide portions is formed between the adjacent convex portions, and each of the slide portions and each of the stop portions are formed at positions above one of the convex portions. The base is disposed on the bottom of the radiator, an inner ring portion is formed at a central position of the base, and the inner ring portion has at least one positioning portion. The positioning portion extends inwardly from the inner ring portion, and the positioning portion is disposed on one of the slide portions and abuts against one of the stop portions. Thereby, the base is displaceable along the slide portion and one of the guide portions through the positioning portion, and is disassembled from the bottom of the radiator, and thus achieving the effect of being conveniently fixed and disassembled.

According to one embodiment of the radiator fixing structure of the present invention, wherein the guide portion communicates with the slide portion, and the guide portion and the slide portion are disposed perpendicularly to each other.

According to one embodiment of the radiator fixing structure of the present invention, wherein at least one positioning hole is formed at a position of the bottom of the radiator, and the positioning hole penetrates the convex portion.

According to one embodiment of the radiator fixing structure of the present invention, wherein a fixing member is disposed in the positioning hole.

According to one embodiment of the radiator fixing structure of the present invention, wherein the positioning portion has an extending portion and is formed with a positioning groove, and the fixing member passes through the positioning groove and is fixed in the positioning hole.

According to one embodiment of the radiator fixing structure of the present invention, wherein a side of the base extends upwardly with at least one expand portion, and the expand portion and the base are disposed perpendicularly to each other.

According to one embodiment of the radiator fixing structure of the present invention, wherein the base is formed with a plurality of locking holes.

According to one embodiment of the radiator fixing structure of the present invention, wherein the radiator is formed with an inclined portion on each of the convex portions.

According to one embodiment of the radiator fixing structure of the present invention, wherein the inner ring portion further extends inwardly with a plurality of ledges, and each of the ledges is disposed on one of the slide portions and abuts against one of the stop portions.

### BRIEF DESCRIPTION OF THE DRAWINGS

FIG. 1 is a perspective assembled view of a preferred embodiment of the present invention;

FIG. 2 is a perspective exploded view of a preferred embodiment of the present invention;

FIG. 3 is a perspective exploded view from another angle of a preferred embodiment of the present invention;

FIG. 4 is a first schematic diagram of the implementation of a preferred embodiment of the present invention;

FIG. 5 is a second schematic diagram of the implementation of a preferred embodiment of the present invention;

FIG. 6 is a third schematic diagram of the implementation of a preferred embodiment of the present invention;

FIG. 7 is a fourth schematic diagram of the implementation of a preferred embodiment of the present invention;

FIG. 8 is a fifth schematic diagram of the implementation of a preferred embodiment of the present invention; and

FIG. 9 is a sixth schematic diagram of the implementation of a preferred embodiment of the present invention.

### DETAILED DESCRIPTION OF THE INVENTION

The above object of the present invention, as well as its structural and functional features, will be described in accordance with the preferred embodiments of the drawings.

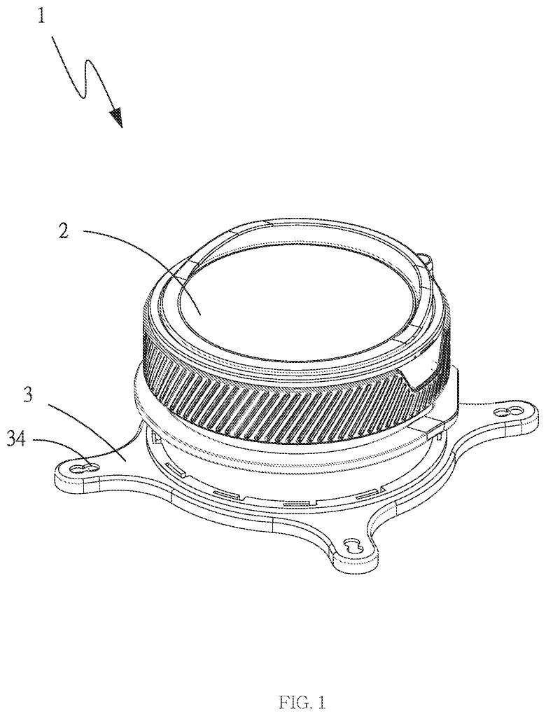

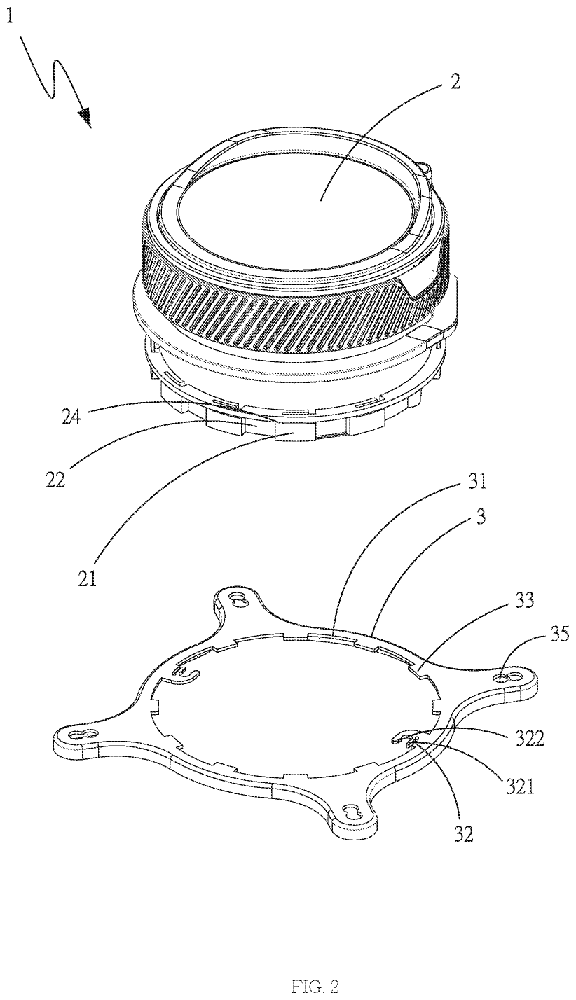

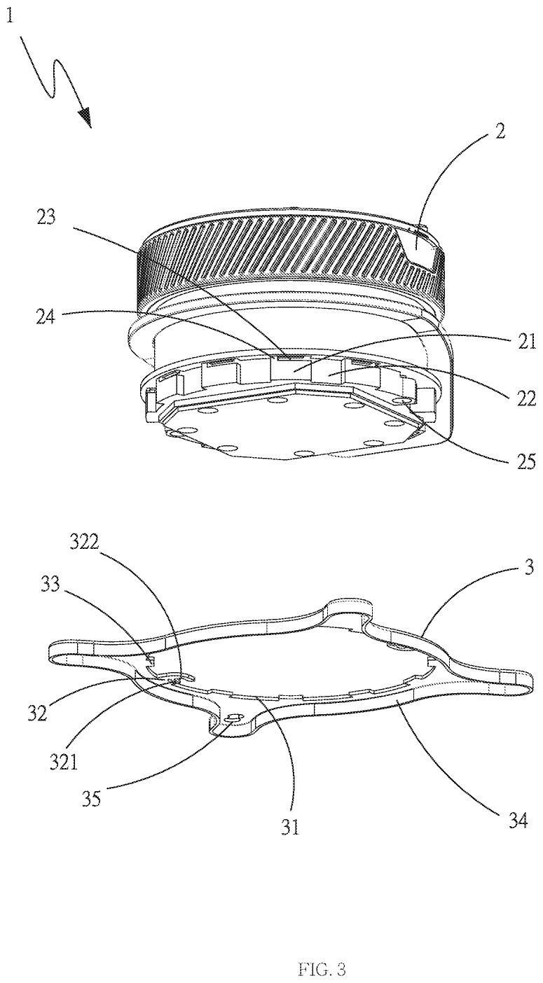

Please refer to FIG. 1 and FIG. 2 and FIG. 3, which are perspective assembled view, perspective exploded view and perspective exploded view from another angle of preferred embodiments of the present invention. It can be clearly seen from the figures that, a radiator fixing structure 1 mainly includes a radiator 2 and a base 3, wherein the radiator 2 is a water-cooled radiator in this embodiment.

Wherein at positions of a bottom the radiator 2 are formed with a plurality of convex portions 21, and the convex portions 21 are formed on a periphery of the radiator 2 and protrude outward from the radiator 2. At positions of the bottom the radiator 2 are formed with a plurality of guide portions 22 and a plurality of slide portions 23 and a plurality of stop portions 24. Each of the guide portions 22 is formed between the adjacent convex portions 21, and each of the slide portions 23 and each of the stop portions 24 are formed at positions above one of the convex portions 21. The guide portion 22 communicates with the slide portion 23, and the guide portion 22 and the slide portion 23 are disposed perpendicularly to each other. At least one positioning hole 25 is formed at a position of the bottom of the radiator 2, the positioning hole 25 penetrates the convex portion 21 partially, and a fixing member 251 is disposed in the positioning hole 25.

The base 3 is disposed at a position of the bottom of the radiator 2, the base 3 is formed with an inner ring portion 31 at a central position, and the inner ring portion 31 has at least one positioning portion 32 and a plurality of ledges 33. The positioning portion 32 and the ledges 33 extend inwardly from the inner ring portion 31, the positioning portion 32 is disposed on the slide portion 23 and abuts against one of the stop portions 24, and the positioning portion 32 has an extending portion 321 and is formed with a positioning groove 322. The fixing member 251 passes through the positioning groove 322 and is fixed in the positioning hole 25. A side of the base 3 extends upwardly with at least one expand portion 34, the expand portion 34 and the base 3 are disposed perpendicularly to each other, and the base 3 is formed with a plurality of locking holes 35.

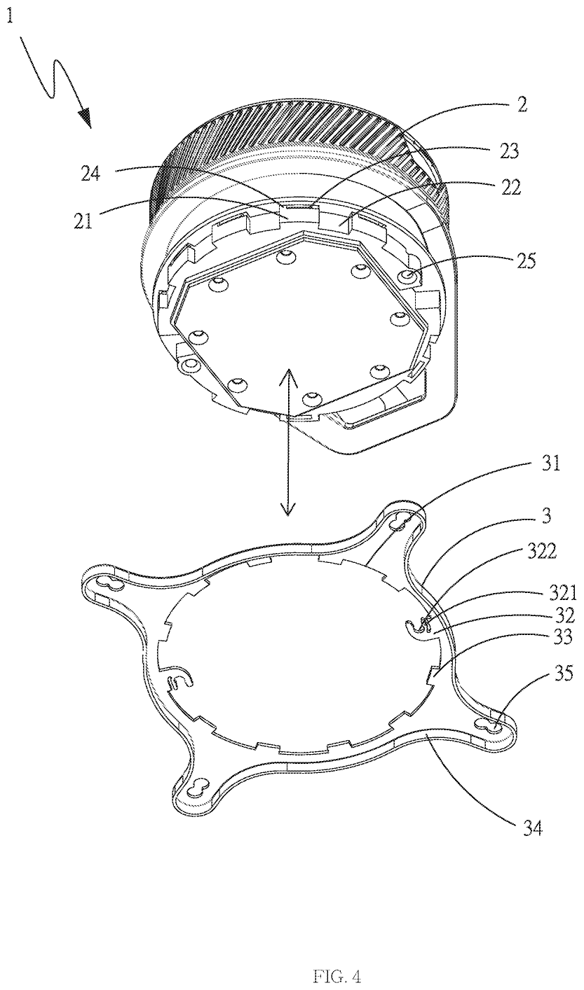

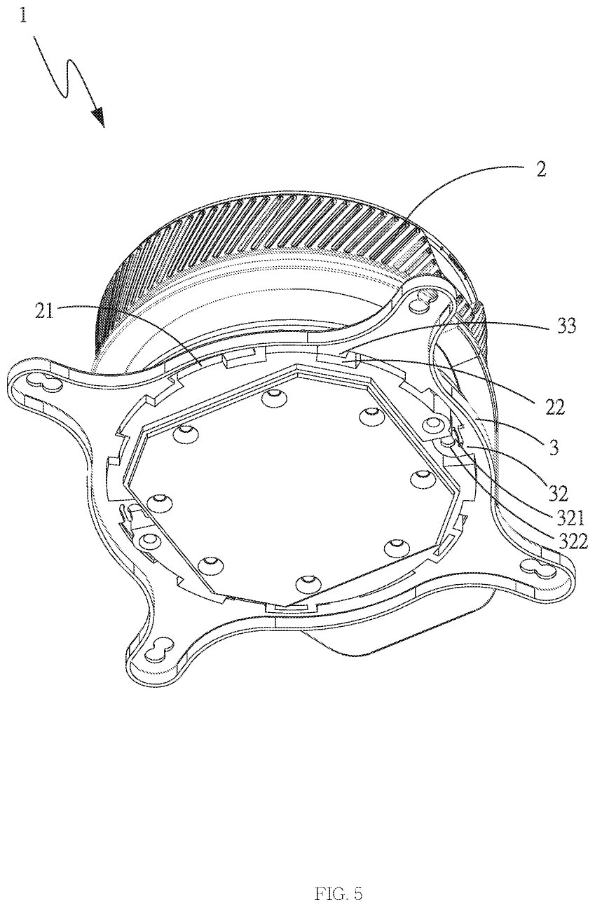

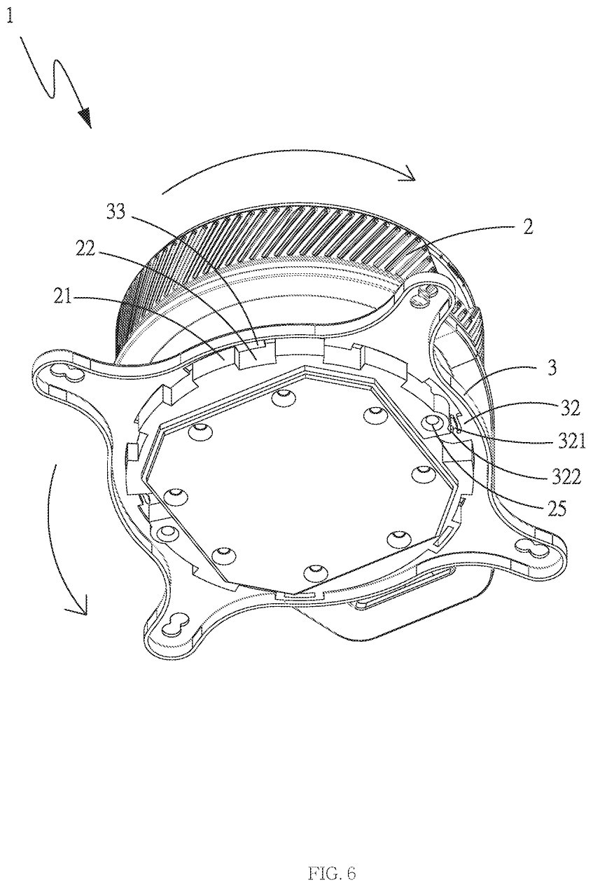

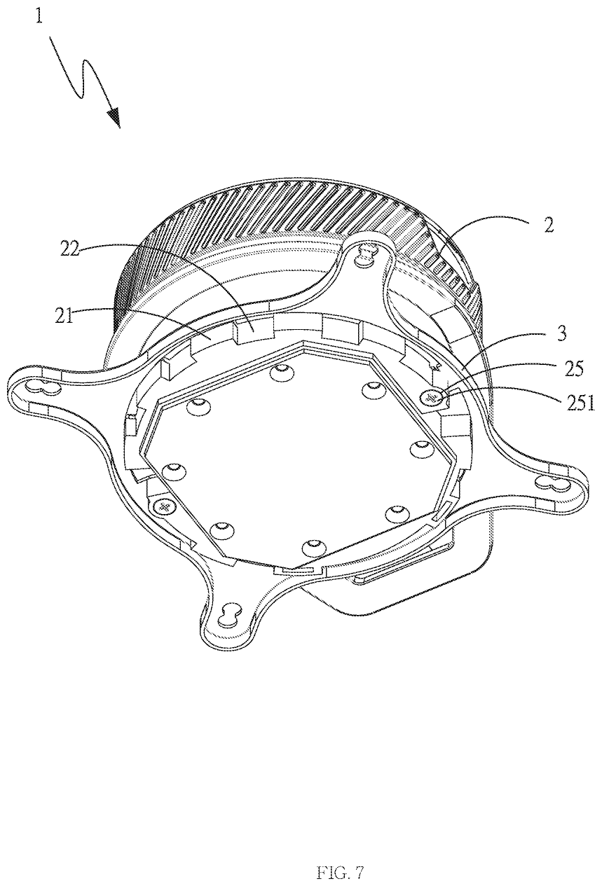

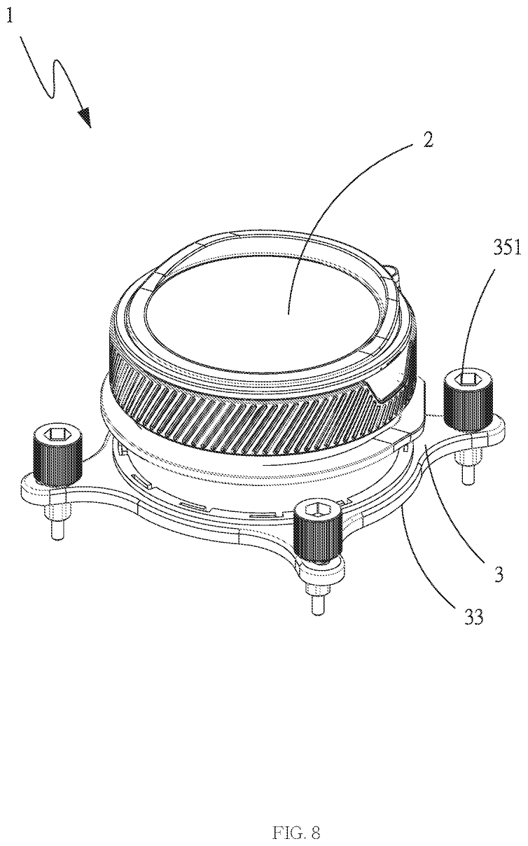

Please refer to the foregoing drawings and FIGS. 4 to 8 for the first to fifth schematic diagrams of the implementation of preferred embodiments of the present invention. It can be clearly seen from the figures that when the radiator 2 and the base 3 are coupled, the positioning portion 32 and the ledges 33 of the inner ring portion 31 of the base 3 are engaged with the guide portions 22 of the radiator 2, so that the positioning portion 32 and the ledges 33 enter the guide portions 22 and move along the guide portions 22 toward the slide portions 23 until the positioning portion 32 and the ledges 33 are moved to reach the slide portions 23. Then the radiator 2 and the base 3 can be rotated, the radiator 2 can be rotated clockwise, or the base 3 can be rotated counterclockwise, so that the positioning portion 32 and the ledges 33 enter into the slide portions 23 until the positioning portion 32 and the ledges 33 are in contact with the stop portions 24. At this time, the radiator 2 can be quickly fixed on the base 3, and vice versa, if the radiator 2 and the base 3 are to be detached, the radiator 2 can be rotated counterclockwise, or the base 3 can be rotated clockwise to disengage the positioning portion 32 and the ledges 33 from the slide portions 23, and then the positioning portion 32 and the ledges 33 are disengaged from the guide portions 22, so that the radiator 2 can be disassembled quickly from the base 3, thereby achieving the effect of being conveniently fixed and disassembled.

The positioning hole 25 is formed in the bottom of the radiator 2, and the positioning hole 25 penetrates the convex portion 21; and the positioning portion 32 has the extending portion 321 and the positioning groove 322; when the radiator 2 and the base 3 are rotated relatively to each other, the positioning groove 322 moves toward the positioning hole 25 and communicates with the positioning hole 25, so that the fixing member 251 passes through the positioning hole 25 while passing through the positioning groove 322, and the fixing member 251 is positioned in the positioning hole 25 and the positioning groove 322 to strengthen the assembled strength between the radiator 2 and the base 3. The extending portion 321 of the positioning portion 32 can be expanded and deformed when the fixing member 251 passes through the positioning groove 322 to effectively avoid the problem of deformation of the positioning groove 322. In addition, the side of the base 3 extends upwardly with the expand portion 34, the expand portion 34 can effectively enhance the overall strength of the base 3, and can effectively support the radiator 2. When at least one fastener 351 passes through the locking hole 35 and is locked to a motherboard, the overall strength of the base 3 can be effectively enhanced at the same time.

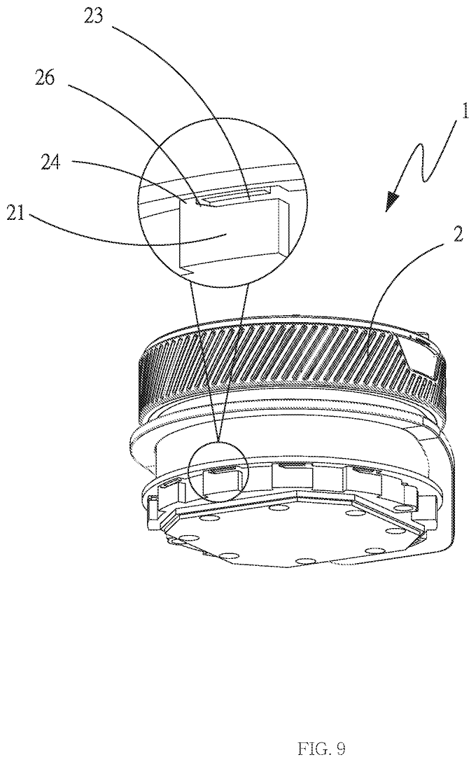

Referring to the foregoing drawings and FIG. 9 at the same time, FIG. 9 is a sixth schematic diagram of the implementation of a preferred embodiment of the present invention. It can be clearly seen from the figure that the radiator 2 is formed with an inclined portion 26 on each of the convex portions 21, when the positioning portion 32 and the ledge 33 pass through the slide portion 23 and contact the stop portion 24, the positioning portion 32 and the ledge 33 are simultaneously tightly engaged by the inclined portion 26, so that the positioning portion 32 and the ledge 33 can be effectively fixed in the slide portion 23 and abut against the stop portion 24. Thereby achieving the effect of being conveniently fixed and disassembled.

It is to be understood that the above description is only preferred embodiments of the present invention and is not used to limit the present invention, and changes in accordance with the concepts of the present invention may be made without departing from the spirit of the present invention, for example, the equivalent effects produced by various transformations, variations, modifications and applications made to the configurations or arrangements shall still fall within the scope covered by the appended claims of the present invention.

What is claimed is:

1. A radiator fixing structure, comprising:
a radiator, at positions of a bottom the radiator being formed with a plurality of convex portions, the radiator being formed with a guide portion between the adjacent convex portions, and the radiator being formed with a slide portion and a stop portion on each of the convex portions; and
a base, the base being disposed on the bottom of the radiator, inside the base having an inner ring portion, the inner ring portion having at least one positioning portion extending inwardly, and the positioning portion being disposed on one of the slide portions and abutting against one of the stop portions.

2. The radiator fixing structure as claimed in claim 1, wherein the guide portion communicates with the slide portion, and the guide portion and the slide portion are disposed perpendicularly to each other

3. The radiator fixing structure as claimed in claim 1, wherein at least one positioning hole is formed at a position of the bottom of the radiator, and the positioning hole penetrates the convex portion.

4. The radiator fixing structure as claimed in claim 3, wherein a fixing member is disposed in the positioning hole.

5. The radiator fixing structure as claimed in claim 4, wherein the positioning portion has an extending portion and is formed with a positioning groove, and the fixing member passes through the positioning groove and is fixed in the positioning hole.

6. The radiator fixing structure as claimed in claim 1, wherein a side of the base extends upwardly with at least one expand portion, and the expand portion and the base are disposed perpendicularly to each other.

7. The radiator fixing structure as claimed in claim 1, wherein the base is formed with a plurality of locking holes.

8. The radiator fixing structure as claimed in claim 1, wherein the radiator is formed with an inclined portion on each of the convex portions.

9. The radiator fixing structure as claimed in claim 1, wherein the inner ring portion further extends inwardly with a plurality of ledges, and each of the ledges is disposed on one of the slide portions and abuts against one of the stop portions.
